(19) United States
(12) Patent Application Publication
(10) Pub. No.: US 2019/0086355 A1
(43) Pub. Date: Mar. 21, 2019

(54) SEMICONDUCTOR APPARATUS INCLUDING A CAPACITANCE MEASURING CIRCUIT

(71) Applicant: SK hynix Inc., Icheon-si Gyeonggi-do (KR)

(72) Inventors: Se Hwan KIM, Icheon-si Gyeonggi-do (KR); Kyeong Tae KIM, Icheon-si Gyeonggi-do (KR); Jae Boum PARK, Seoul (KR)

(73) Assignee: SK hynix Inc., Icheon-si Gyeonggi-do (KR)

(21) Appl. No.: 15/952,870

(22) Filed: Apr. 13, 2018

(30) Foreign Application Priority Data
Sep. 19, 2017 (KR) 10-2017-0120619

(51) Int. Cl. G01N 27/22; G01R 27/26

(52) U.S. Cl. CPC G01N 27/228; G01R 27/2605

(57) ABSTRACT

A semiconductor apparatus may include a capacitance measuring circuit. The capacitance measuring circuit may include a constant current circuit configured to output a constant current. The capacitance measuring circuit may include a voltage converting circuit configured to convert the constant current into a detection voltage, and compensate for a variation of the detection voltage due to internal leakage current of the voltage converting circuit. The capacitance measuring circuit may include a code generating circuit configured to generate a value obtained by detecting a time elapsed while the detection voltage increases to a reference voltage, as a code signal.

### CROSS-REFERENCES TO RELATED APPLICATION

The present application claims priority under 35 U.S.C. § 119(a) to Korean application number 10-2017-0120619, filed on Sep. 19, 2017, in the Korean Intellectual Property Office, which is incorporated herein by reference in its entirety.

### BACKGROUND

### 1. Technical Field

Various embodiments generally relate to a semiconductor circuit, and, more particularly, to a capacitance measuring circuit included in a semiconductor apparatus.

### 2. Related Art

A semiconductor apparatus may be configured by a plurality of devices having capacitances, such as transistors and capacitors.

In the case where the capacitances of the above-described devices deviate from target values in a manufacturing process, a substantial influence may be exerted on the operation performance of the corresponding semiconductor apparatus.

Therefore, a circuit configuration capable of accurately measuring the capacitance of a device configuring the semiconductor apparatus is needed.

### SUMMARY

In an embodiment, a semiconductor apparatus including a capacitance measuring circuit may be provided. The capacitance measuring circuit may include a constant current circuit configured to output a constant current. The capacitance measuring circuit may include a voltage converting circuit configured to convert the constant current into a detection voltage, and compensate for a variation of the detection voltage due to internal leakage current of the voltage converting circuit. The capacitance measuring circuit may include a code generating circuit configured to generate a value obtained by detecting a time elapsed while the detection voltage increases to a reference voltage, as a code signal.

In an embodiment, a semiconductor apparatus including a capacitance measuring circuit and a device under test may be provided. The capacitance measuring circuit may include a current source configured to generate a constant current. The capacitance measuring circuit may include a first switching circuit configured to supply the constant current to the device under test which outputs a charged voltage as a detection voltage, depending on a test mode signal. The capacitance measuring circuit may include a second switching circuit configured to reset a voltage level of a node through which the detection voltage is outputted, to a level of a ground terminal. The capacitance measuring circuit may include a comparator configured to generate a comparison signal by comparing a reference voltage and the detection voltage. The capacitance measuring circuit may include a counter configured to output a code signal by counting the comparison signal as an oscillation signal.

### BRIEF DESCRIPTION OF THE DRAWINGS

FIG. 1 is a diagram illustrating a representation of an example of the configuration of a semiconductor apparatus 1 in accordance with an embodiment.

FIG. 2 is a diagram illustrating a representation of an example of the configuration of a capacitance measuring circuit 100 included in a semiconductor apparatus in accordance with an embodiment.

FIG. 3 is a diagram illustrating a representation of an example of the configuration of the constant current circuit 200 illustrated in FIG. 2.

FIG. 4 is a diagram illustrating a representation of an example of the configuration of the voltage converting circuit 300 illustrated in FIG. 2.

FIG. 5 is a diagram illustrating a representation of an example of the configuration of the code generating circuit 400 illustrated in FIG. 2.

FIG. 6 is a diagram illustrating a representation of an example of the configuration of the control logic 430 illustrated in FIG. 5.

### DETAILED DESCRIPTION

Various embodiments may be directed to a capacitance measuring circuit included with a semiconductor apparatus and capable of accurately measuring the capacitance of a device included in the semiconductor apparatus.

For reference, an embodiment including additional components may be provided. Furthermore, a high level or low level configuration indicating an active state of a signal or circuit may be changed depending on embodiments. Furthermore, the configuration of a transistor required for implementing the same function may be modified. That is, the configuration of the PMOS transistor and the configuration of the NMOS transistor may be replaced with each other, depending on a specific situation. If necessary, various transistors may be applied to implement the configurations.

For reference, an embodiment including additional components may be provided. Furthermore, a high level or low level configuration indicating an active state of a signal or circuit may be changed depending on embodiments. Furthermore, the configuration of a logic gate or logic gates required for implementing the same function or operation may be modified. That is, the logic gate configuration of one type of operation and another logic gate configuration for the same type of operation may be replaced with each other, depending on a specific situation. If necessary, various logic gates may be applied to implement the configurations.

Further, the logic levels of the signals may be different from or the opposite of those described. For example, a signal described as having a logic “high” level may alternatively have a logic “low” level, and a signal described as having a logic “low” level may alternatively have a logic “high” level.

Hereinafter, a semiconductor apparatus including a capacitance measuring circuit will be described below with reference to the accompanying drawings through various examples of embodiments.

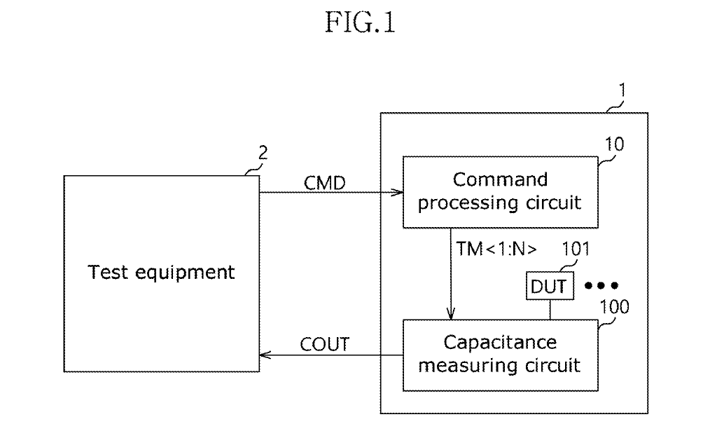

As illustrated in FIG. 1, a semiconductor apparatus 1 in accordance with an embodiment may include a capacitance measuring circuit 100, a command processing circuit 10 and a device under test (DUT) 101.

The command processing circuit 10 may generate a plurality of test mode signals TM<1:N> by decoding a command CMD provided from external test equipment 2.

The capacitance measuring circuit 100 may provide a code signal COUT generated by measuring the capacitance of the device under test 101 depending on the plurality of test mode signals TM<1:N>, to the test equipment 2.

The device under test 101 may be any one of various circuit components in the semiconductor apparatus 1, and may be, for example, a capacitor which is included in a memory cell.

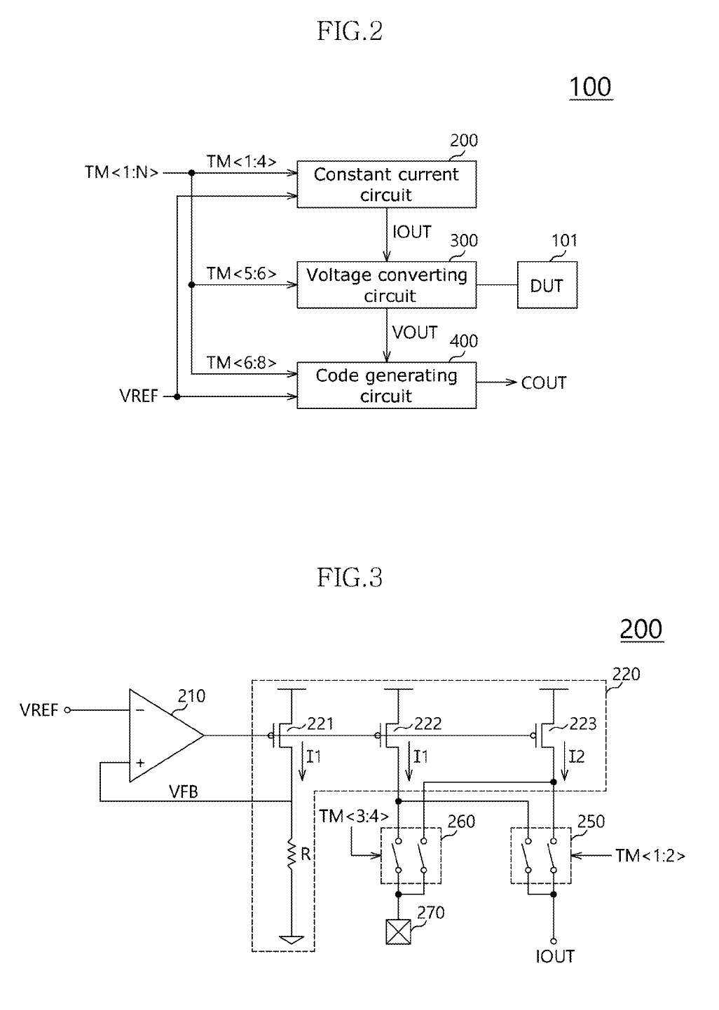

As illustrated in FIG. 2, the capacitance measuring circuit 100 in accordance with an embodiment may include a constant current circuit 200, a voltage converting circuit 300 and a code generating circuit 400.

The constant current circuit 200 as a current source for generating a constant current, that is, a direct current (DC) current, may generate a plurality of currents having different current amounts depending on a reference voltage VREF, may select one of the plurality of currents as a constant current IOUT depending on the test mode signals TM<1:4> among the plurality of test mode signals TM<1:N>, and may output the constant current IOUT to an interior or an exterior.

The voltage converting circuit 300 may generate a detection voltage VOUT which increases depending on the constant current IOUT and the capacitance of the device under test 101, depending on the test mode signals TM<5:6> among the plurality of test mode signals TM<1:N>, and may compensate for the variation of the detection voltage VOUT by internal leakage current.

The detection voltage VOUT may linearly increase depending on a time and a current, and its slope may be proportional to the constant current IOUT and inversely proportional to the capacitance of the device under test 101.

The code generating circuit 400 may generate a value obtained by detecting a time elapsed while the detection voltage VOUT increases to the reference voltage VREF and eventually equals the reference voltage VREF value, as the code signal COUT, depending on the test mode signals TM<6:8> among the plurality of test mode signals TM<1:N>.

As illustrated in FIG. 3, the constant current circuit 200 may include a comparator 210, a current mirror 220, a first switching circuit 250 and a second switching circuit 260.

The comparator 210 may amplify and output the difference of a feedback voltage VFB and the reference voltage VREF.

The current mirror 220 may select one of the currents from the currents I1 and 12 mirrored depending on the output of the comparator 210, depending on the test mode signals TM<1:4>, and output the selected one as the constant current IOUT.

The current mirror 220 may include first to third transistors 221 to 223 and a resistor R.

The first transistor 221 may have a source which is electrically coupled with a power supply terminal, a drain which is electrically coupled with the resistor R and a gate which receives the output of the comparator 210.

The feedback voltage VFB may be generated by the first current I1 which flows from the drain of the first transistor 221 through the resistor R.

The second transistor 222 may have a source which is electrically coupled with the power supply terminal, a drain which is electrically coupled with the second switching circuit 260 and a gate which receives the output of the comparator 210.

The second transistor 222 may be designed the same as the first transistor 221, and may have the same current drivability as the first transistor 221.

Therefore, the first current I1 of the same amount as in the first transistor 221 may flow through the second transistor 222.

The third transistor 223 may have a source which is electrically coupled with the power supply terminal, a drain which is electrically coupled with the first switching circuit 250 and a gate which receives the output of the comparator 210.

The third transistor 223 may be designed differently from the first transistor 221, and may have different current drivability from the first transistor 221.

Therefore, the second current I2 of a different amount as in the first transistor 221 may flow through the third transistor 223.

The first switching circuit 250 may output one of the first current I1 and the second current I2 as the constant current IOUT depending on the test mode signals TM<1:2>.

The second switching circuit 260 may output one of the first current I1 and the second current I2 through a pad 270 to an exterior of the semiconductor apparatus 1, depending on the test mode signals TM<3:4>.

The embodiment shows a mere example of configuring the current mirror 220 to mirror the first current I1 and the second current I2, and may be implemented to mirror an increased number of currents, as the occasion demands. In this regard, it is to be noted that the numbers of transistors or/and resistors configuring the current mirror 220 and electrical coupling relationships among them may be changed depending on a modification in configuration.

The pad 270 may be one among the data input/output pads (DQ) of the semiconductor apparatus 1.

The operation of the constant current circuit 200 as illustrated in FIG. 3 is as follows.

First, although not essential to capacitance measurement according to the embodiments, in order to allow the capacitance measurement to be accurately performed, it may be possible to check whether the amount of a current actually supplied from the constant current circuit 200 corresponds to a target amount.

In an embodiment, in the state in which all the switches of the first switching circuit 250 are turned off through using the test mode signals TM<1:2>, one of the first current I1 and the second current I2 may be outputted to the test equipment 2 through the pad 270 by turning on one of the switches of the second switching circuit 260 through using the test mode signals TM<3:4>.

Thus, by using the test equipment 2, it is possible to check whether the current amount of any one selected between the first current I1 and the second current I2 corresponds to a target amount.

After the above-described current amount checking is completed, any one current selected between the first current I1 and the second current I2 may be supplied to the voltage converting circuit 300 by turning off all the switches of the second switching circuit 260 through using the test mode signals TM<3:4> and by controlling the switches of the first switching circuit 250 through using the test mode signals TM<1:2>.

As illustrated in FIG. 4, the voltage converting circuit 300 may include first to third switching circuits 310 to 330.

The first switching circuit 310 may be electrically coupled between the line of the constant current IOUT, that is, a power line for transmitting the constant current IOUT, and the device under test 101.

The first switching circuit 310 may charge the constant current IOUT to the device under test 101 depending on the test mode signal TM<5>.

The device under test 101 may output a voltage generated by charging the constant current IOUT, as the detection voltage VOUT.

The second switching circuit 320 may be electrically coupled between the line of the constant current IOUT and a ground terminal.

The second switching circuit 320 may discharge the constant current IOUT through the ground terminal depending on the test mode signal TM<6>.

The third switching circuit 330 may be electrically coupled between the power supply terminal and the line of the constant current IOUT.

The operation of the voltage converting circuit 300 as illustrated in FIG. 4 is as follows.

The voltage converting circuit 300 may operate for converting the constant current IOUT supplied from the constant current circuit 200 of FIG. 3 into a voltage form, that is, the detection voltage VOUT.

Before converting the constant current IOUT into the detection voltage VOUT, a process of resetting the node of the detection voltage VOUT to an initial level, for example, 0V, is necessary.

By turning on the second switching circuit 320 through using the test mode signal TM<6> of a logic high, it is possible to reset the node of the detection voltage VOUT to the initial level, for example, 0V.

Thereafter, as the second switching circuit 320 is turned off by causing the test mode signal TM<6> to transition to a logic low, the constant current IOUT is supplied to the node of the detection voltage VOUT, and accordingly, the detection voltage VOUT increases linearly.

The third switching circuit 330 retains a turned-off state without being separately controlled.

The third switching circuit 330 may have the same characteristic as the second switching circuit 320.

Each of the first to third switching circuits 310 to 330 may be configured by a switching device such as a transistor. In the turned-off state of a device such as a transistor, leakage current may be caused.

In an embodiment, the second switching circuit 320 retains a turned-off state after the node of the detection voltage VOUT is reset, and leakage current may occur to the ground terminal in the turned-off state of the second switching circuit 320. Therefore, an error in capacitance measurement may be compensated for through compensating for a current corresponding to the leakage current caused in the second switching circuit 320 by the leakage current of the third switching circuit 330 which retains the turned-off state.

As illustrated in FIG. 5, the code generating circuit 400 may include a switching circuit 410, a comparator 420, a control logic 430, an oscillator 440, a logic gate 450 and a counter 460.

The comparator 420 may generate a comparison signal CMP by amplifying the voltage difference of a first input terminal + and a second input terminal −.

The switching circuit 410 may input any one of the detection voltage VOUT and the reference voltage VREF to the first input terminal + of the comparator 420 and input the other to the second input terminal −, depending on the test mode signals TM<7:8>.

The switching circuit 410 may input the detection voltage VOUT and the reference voltage VREF to the first input terminal + and the second input terminal −, respectively, of the comparator 420 in the case where the test mode signals TM<7:8> are low levels.

The switching circuit 410 may input the detection voltage VOUT and the reference voltage VREF to the second input terminal − and the first input terminal +, respectively, of the comparator 420 in the case where the test mode signals TM<7:8> are high levels.

The control logic 430 may generate an oscillation enable signal OSC_EN and a counting enable signal CNT_EN by combining the comparison signal CMP and the test mode signals TM<6:8>.

The oscillator 440 may generate an oscillation signal OSC for the activation period of the oscillation enable signal OSC_EN.

The logic gate 450 may perform a NAND logic function on the oscillation signal OSC and the counting enable signal CNT_EN, and output an output signal.

The counter 460 may count the comparison signal CMP as the oscillation signal OSC for the activation period of the counting enable signal CNT_EN, and output the code signal COUT.

That is to say, the counter 460 may output a value obtained by counting the falling edge of the output signal of the logic gate 450, as the code signal COUT, through a pad 470 to an exterior of the semiconductor apparatus 1.

The pad 470 may be one among the data input/output pads (DQ) of the semiconductor apparatus 1.

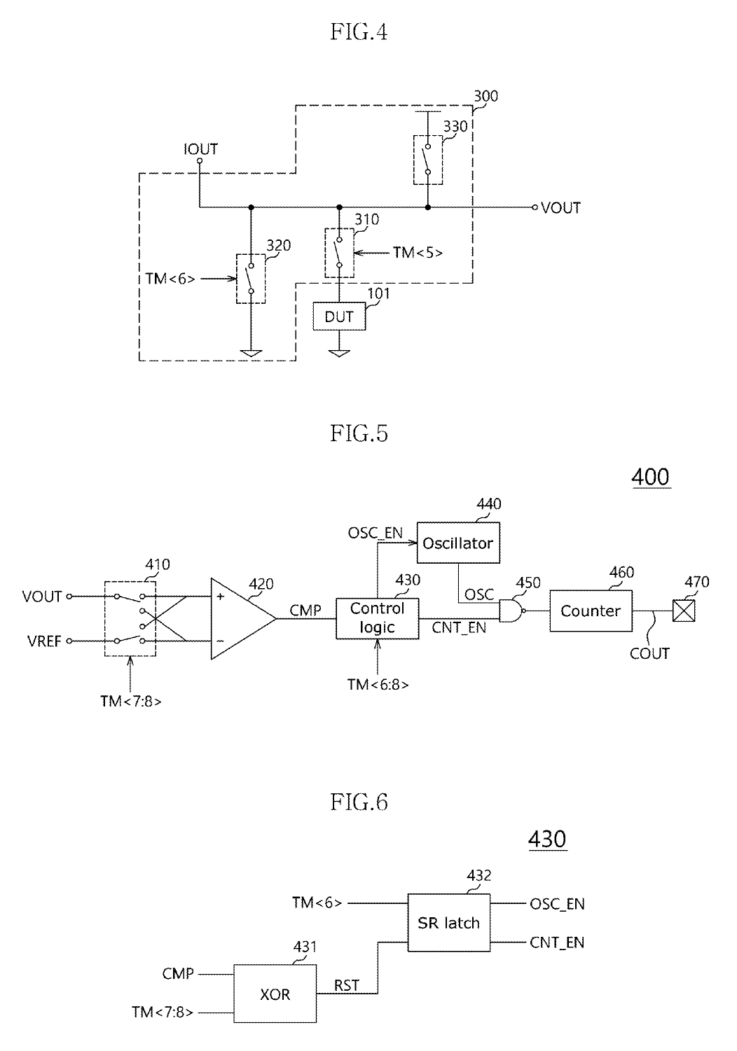

As illustrated in FIG. 6, the control logic 430 may include a logic gate 431 and an set-reset (SR) latch 432. [SR in SR latch was defined as set-reset in original paragraph 73 of the detailed description.]

The logic gate 431 may output a result of performing an XOR function on the comparison signal CMP and the test mode signals TM<7:8>, as a reset signal RST.

The logic gate 431 may activate the reset signal RST to a high level when the comparison signal CMP transitions from a low level to a high level in the case where the test mode signals TM<7:8> are the low levels.

The logic gate 431 may activate the reset signal RST to the high level when the comparison signal CMP transitions from the high level to the low level in the case where the test mode signals TM<7:8> are the high levels.

The SR latch 432 may activate the oscillation enable signal OSC_EN and the counting enable signal CNT_EN to high levels according to the falling edge of the test mode signal TM<6>.

The SR latch 432 may deactivate the oscillation enable signal OSC_EN and the counting enable signal CNT_EN to low levels as the reset signal RST is activated.

Hereafter, the capacitance measuring operation of the semiconductor apparatus 1 in accordance with an embodiment will be described.

In an embodiment, in the case where the first switching circuit 310 is turned off through using the test mode signal TM<5>, since current supply to the device under test 101 is cut off, it is possible to measure not the capacitance of the device under test 101 but the capacitance, that is, the parasitic capacitance (denoted by Cpar for convenience in explanation), of the capacitance measuring circuit 100 itself.

In the case where the first switching circuit 310 is tuned on, it is possible to measure a total capacitance (denoted by Ctot for convenience in explanation) as the sum of the parasitic capacitance Cpar and the capacitance (denoted by Cdut for convenience in explanation) of the device under test 101.

Thus, an expression Cdut=Ctot−Cpar is satisfied.

As a result, by performing primary capacitance measurement in the state in which the first switching circuit 310 is turned off and then performing a secondary capacitance measurement in the state in which the first switching circuit 310 is turned on, the capacitance Cdut of only the device under test 101 may be calculated.

First, the primary capacitance measurement in which only the capacitance of the capacitance measuring circuit 100 itself is measured with the first switching circuit 310 turned off may be performed as follows.

By turning on the second switching circuit 320 through retaining the test mode signal TM<6> at the high level for a predetermined time, it is possible to reset the node of the detection voltage VOUT to the initial level, for example, 0V.

As the test mode signal TM<6> transitions from the high level to the low level, the control logic 430 activates the oscillation enable signal OSC_EN and the counting enable signal CNT_EN.

As the oscillation enable signal OSC_EN is activated, the oscillator 440 generates the oscillation signal OSC.

As the test mode signal TM<6> transitions to the low level, the second switching circuit 320 is turned off and the constant current IOUT is supplied to the node of the detection voltage VOUT, and accordingly, the detection voltage VOUT increases linearly.

At this time, since the first switching circuit 310 is in the turned-off state, the supply of the constant current IOUT to the device under test 101 is cut off.

The detection voltage VOUT and the reference voltage VREF may be inputted to the first input terminal + and the second input terminal −, respectively, of the comparator 420 depending on the test mode signals TM<7:8>.

In the case where the detection voltage VOUT is lower than the reference voltage VREF, the comparator 420 outputs the comparison signal CMP at the low level.

The counter 460 increases the value of the code signal COUT by counting the falling edge of the oscillation signal OSC which is inverted through the logic gate 450, for a period in which the counting enable signal CNT_EN is activated.

If the detection voltage VOUT rises and becomes equal to or higher than the reference voltage VREF, the comparator 420 outputs the comparison signal CMP at the high level, and accordingly, the oscillation enable signal OSC_EN and the counting enable signal CNT_EN are reset to the low levels.

Therefore, since the output of the logic gate 450 is retained at a high level, the counter 460 retains the current value of the code signal COUT.

As a result, since the value of the code signal COUT may differ according to whether the capacitance of the capacitance measuring circuit 100 itself is large or small, the value of the code signal COUT may be used as a capacitance measurement value.

Since the comparator 420 may have a basic offset, inputs to the first input terminal + and the second input terminal − are reversed through using the test mode signals TM<7:8>. In other words, after inputting the reference voltage VREF to the first input terminal + and inputting the detection voltage VOUT to the second input terminal −, the above-described process for generating the code signal COUT is repeated.

By calculating the average of the value of the code signal COUT generated in the state in which the detection voltage VOUT and the reference voltage VREF are inputted to the first input terminal + and the second input terminal −, respectively, of the comparator 420 and the value of the code signal COUT generated by reversing the inputs, an error in capacitance measurement by the offset of the comparator 420 itself may be eliminated.

Next, the secondary capacitance measurement in the state in which the first switching circuit 310 is turned on may be performed as follows.

By turning on the second switching circuit 320 through retaining the test mode signal TM<6> at the high level for the predetermined time, it is possible to reset the node of the detection voltage VOUT to the initial level, for example, 0V.

As the test mode signal TM<6> transitions from the high level to the low level, the control logic 430 activates the oscillation enable signal OSC_EN and the counting enable signal CNT_EN.

As the oscillation enable signal OSC_EN is activated, the oscillator 440 generates the oscillation signal OSC.

As the test mode signal TM<6> transitions to the low level, the second switching circuit 320 is turned off, and at the same time with this or after a predetermined time, the first switching circuit 310 is turned on through using the test mode signal TM<5>.

As the first switching circuit 310 is turned on, the constant current IOUT starts to be charged to the device under test 101 (see FIG. 4), and, as the constant current IOUT is supplied to the node of the detection voltage VOUT, the detection voltage VOUT increases linearly.

The detection voltage VOUT and the reference voltage VREF may be inputted to the first input terminal + and the second input terminal −, respectively, of the comparator 420 depending on the test mode signals TM<7:8>.

In the case where the detection voltage VOUT is lower than the reference voltage VREF, the comparator 420 outputs the comparison signal CMP at the low level.

Accordingly, the counter 460 increases the value of the code signal COUT by counting the falling edge of the oscillation signal OSC which is inverted through the logic gate 450.

If the detection voltage VOUT rises and becomes equal to or higher than the reference voltage VREF, the comparator 420 outputs the comparison signal CMP at the high level, and accordingly, the oscillation enable signal OSC_EN and the counting enable signal CNT_EN are reset to the low levels.

Therefore, since the output of the logic gate 450 is retained at the high level, the counter 460 retains the current value of the code signal COUT.

As a result, since the value of the code signal COUT may differ according to whether the capacitances of the device under test 101 and the capacitance measuring circuit 100 itself are large or small, the value of the code signal COUT may be used as a capacitance measurement value.

Since the comparator 420 may have the basic offset, inputs to the first input terminal + and the second input terminal − are reversed through using the test mode signals TM<7:8>. In other words, after inputting the reference voltage VREF to the first input terminal +and inputting the detection voltage VOUT to the second input terminal −, the above-described process for generating the code signal COUT is repeated.

By calculating the average of the value of the code signal COUT generated in the state in which the detection voltage VOUT and the reference voltage VREF are inputted to the first input terminal + and the second input terminal −, respectively, of the comparator 420 and the value of the code signal COUT generated by reversing the inputs, an error in capacitance measurement by the offset of the comparator 420 itself may be eliminated.

While various embodiments have been described above, it will be understood to those skilled in the art that the embodiments described are examples only. Accordingly, the capacitance measuring circuit of a semiconductor apparatus described herein should not be limited based on the described embodiments.

What is claimed is:

1. A semiconductor apparatus comprising:
a capacitance measuring circuit, comprising:
a constant current circuit configured to output a constant current;
a voltage converting circuit configured to convert the constant current into a detection voltage, and compensate for a variation of the detection voltage due to internal leakage current of the voltage converting circuit; and
a code generating circuit configured to generate a value obtained by detecting a time elapsed while the detection voltage increases to a reference voltage, as a code signal.

2. The semiconductor apparatus according to claim 1, further comprising:
a device under test,
wherein the voltage converting circuit converts the constant current into a detection voltage based on the constant current received from the constant current circuit and a capacitance of the device under test to generate the detection voltage.

3. The semiconductor apparatus according to claim 1, wherein the constant current circuit is configured to generate a plurality of currents depending on the reference voltage and output one among the plurality of currents as the constant current.

4. The semiconductor apparatus according to claim 1, wherein the constant current circuit comprises:
a comparator configured to amplify and output a difference of a feedback voltage and the reference voltage;
a current mirror configured to generate the plurality of currents having different current amounts depending on an output of the comparator; and
a first switching circuit configured to output the constant current by selecting one among the plurality of currents.

5. The semiconductor apparatus according to claim 4, wherein the constant current circuit further comprises:
a second switching circuit configured to output one among the plurality of currents, through a pad to an exterior of the semiconductor apparatus.

6. The semiconductor apparatus according to claim 1,
further comprising:
a device under test,
wherein the voltage converting circuit comprises:
a first switching circuit electrically coupled between a constant current line and the device under test;
a second switching circuit electrically coupled between the constant current line and a ground terminal; and
a third switching circuit electrically coupled between a power supply terminal and the constant current line.

7. The semiconductor apparatus according to claim 6, wherein the third switching circuit is configured to retain a turned-off state without being separately controlled.

8. The semiconductor apparatus according to claim 1, wherein the code generating circuit comprises:
a comparator configured to generate a comparison signal by amplifying a voltage difference of the detection voltage and the reference voltage;
a control logic configured to generate an oscillation enable signal and a counting enable signal depending on the comparison signal;
an oscillator configured to generate an oscillation signal for an activation period of the oscillation enable signal;
a logic gate configured to output an output signal by combining the oscillation signal and the counting enable signal; and
a counter configured to output a value obtained by counting the output signal of the logic gate, as the code signal.

9. The semiconductor apparatus according to claim 8, further comprising:
a device under test,
wherein the control logic comprises:
a logic gate configured to generate a reset signal depending on the comparison signal; and
a set-reset (SR) latch configured to generate the oscillation enable signal and the counting enable signal depending on a test mode signal for controlling a time at which the constant current is supplied to the device under test and the reset signal.

10. The semiconductor apparatus according to claim 8, wherein the code generating circuit further comprises:
a switching circuit configured to input any one of the detection voltage and the reference voltage to a first input terminal of the comparator and input the other to a second input terminal.

11. The semiconductor apparatus according to claim 8, wherein the counter outputs the code signal through a pad to an exterior of the semiconductor apparatus.

12. A semiconductor apparatus comprising:
a device under test; and
a capacitance measuring circuit comprising:
a current source configured to generate a constant current;
a first switching circuit configured to supply the constant current to the device under test which outputs a charged voltage as a detection voltage, depending on a test mode signal;
a second switching circuit configured to reset a voltage level of a node through which the detection voltage is outputted, to a level of a ground terminal;
a comparator configured to generate a comparison signal by comparing a reference voltage and the detection voltage; and
a counter configured to output a code signal by counting the comparison signal as an oscillation signal.

13. The semiconductor apparatus according to claim 12, wherein the current source is configured to generate a plurality of currents having different current amounts and output the constant current by selecting one among the plurality of currents.

14. The semiconductor apparatus according to claim 12, further comprising:
a third switching circuit electrically coupled between a power supply terminal and a node through which the detection voltage is outputted, and configured to leak a current corresponding to leakage current caused in the second switching circuit, to the node through which the detection voltage is outputted.

15. The semiconductor apparatus according to claim 14, further comprising:
a fourth switching circuit configured to input any one of the detection voltage and the reference voltage to a first input terminal of the comparator and input the other to a second input terminal of the comparator.

16. The semiconductor apparatus according to claim 12, further comprising:
a control logic configured to generate an oscillation enable signal depending on the test mode signal and the comparison signal; and
an oscillator configured to generate the oscillation signal for an activation period of the oscillation enable signal.

17. The semiconductor apparatus according to claim 16, wherein the control logic comprises:
a logic gate configured to generate a reset signal depending on the comparison signal; and
a set-reset (SR) latch configured to generate the oscillation enable signal depending on the test mode signal and the reset signal.
